(19) United States
(12) Patent Application Publication
(10) Pub. No.: US 2023/0054464 A1
(43) Pub. Date: Feb. 23, 2023

(54) ETCHING DEFECT DETECTION METHOD

(71) Applicant: CHANGXIN MEMORY TECHNOLOGIES, INC., Hefei City, Anhui (CN)

(72) Inventors: Tao LIU, Hefei City, Anhui (CN); Sen LI, Hefei City, Anhui (CN); Qiang WAN, Hefei City, Anhui (CN)

(21) Appl. No.: 17/600,286

(22) PCT Filed: Jun. 30, 2021
(86) PCT No.: PCT/CN2021/103786

§ 371 Date: Sep. 30, 2021

(30) Foreign Application Priority Data
Sep. 10, 2020 (CN) 202010946739.7

(51) Int. Cl. H01L 21/66; H01L 27/108; G06T 7/00; G06T 7/90

(52) U.S. Cl. CPC H01L 22/12; H01L 27/1085; G06T 7/0004; G06T 7/90; G06T 2207/10061; G06T 2207/30148; G06T 2207/10024

(57) ABSTRACT

The present disclosure provides an etching defect detection method, relating to the field of semiconductor technology. The detection method includes: providing a substrate, and sequentially forming a conductive layer and a dielectric layer on the substrate; etching the dielectric layer to form a trench structure; taking the conductive layer as a cathode, and filling the trench structure with an electroplating layer by an electroplating process, to form a product to-be-detected; and testing the product to-be-detected by a defect density detection assembly, to obtain a top-view image of the trench structure, and determining an etching defect of the product to-be-detected according to the top-view image. The etching defect detection method can improve the accuracy of defect identification and prevent a capacitor from failing due to suspension.

### CROSS-REFERENCE TO RELATED APPLICATIONS

The present application is a national stage of International Patent Application No. PCT/CN2021/103786, filed on Jun. 30, 2021, which claims the priority to Chinese Patent Application No. 202010946739.7, titled “ETCHING DEFECT DETECTION METHOD”, filed on Sep. 10, 2020. The entire contents of International Patent Application No. PCT/CN2021/103786 and Chinese Patent Application No. 202010946739.7 are incorporated herein by reference.

### TECHNICAL FIELD

The present disclosure relates to the field of semiconductor technology, and specifically relates to an etching defect detection method.

### BACKGROUND

Dynamic Random Access Memory (DRAM) are widely used in mobile devices such as mobile phones and tablet computers because of their advantages such as small size, high degree of integration and fast transmission speed. As a core component of a dynamic random access memory, a capacitor is mainly used to store charges.

Generally, in the process of manufacturing a capacitor, a dielectric layer needs to be etched to form a trench structure with a depth feature. During the etching of the trench structure, defects easily occur in the trench structure due to insufficient etching. Therefore, effective identification of etching defects becomes increasingly critical.

It should be noted that the information disclosed in the background section above is only used to enhance the understanding of the background of the present disclosure, and therefore may include information that does not constitute the prior art known to those of ordinary skill in the art.

### SUMMARY

According to an aspect of the present disclosure, an etching defect detection method is provided. The etching defect detection method includes:

providing a substrate, and sequentially forming a conductive layer and a dielectric layer on the substrate;

etching the dielectric layer to form a trench structure;

taking the conductive layer as a cathode, and filling the trench structure with an electroplating layer by an electroplating process, to form a product to-be-detected; and

testing the product to-be-detected by a defect density detection assembly, to obtain a top-view image of the trench structure, and determining an etching defect of the product to-be-detected according to the top-view image.

### BRIEF DESCRIPTION OF THE DRAWINGS

The accompanying drawings herein are incorporated into the specification and constitute a part of the specification, show embodiments consistent with the present disclosure, and are used to explain the principle of the present disclosure together with the specification. Apparently, the drawings described below are only some of the drawings of the present disclosure, and other drawings may also be obtained by those of ordinary skill in the art according to these drawings without any creative efforts.

FIG. 1 is a schematic structure diagram of a substrate, a support layer, and a dielectric layer in related technologies.

FIG. 2 is a top view of the substrate, the support layer and the dielectric layer in the related technologies.

FIG. 3 is a flowchart of an etching defect detection method according to an embodiment of the present disclosure.

FIG. 4 is a schematic structure diagram after step S120 in FIG. 3 is completed.

FIG. 5 is a flowchart corresponding to step S120 in FIG. 3.

FIG. 6 is a schematic structure diagram after step S130 in FIG. 3 is completed.

FIG. 7 is a flowchart corresponding to step S130 in FIG. 3.

FIG. 8 is a schematic diagram of an electroplating layer according to an embodiment of the present disclosure.

FIG. 9 is a top-view image of a trench structure according to an embodiment of the present disclosure.

### DETAILED DESCRIPTION

Example embodiments are now described more comprehensively with reference to the accompanying drawings. However, the example embodiments can be implemented in various forms, and should not be construed as being limited to the examples set forth herein; on the contrary, the provision of these embodiments makes the present disclosure more comprehensive and complete, and fully conveys the concept of the example embodiments to those skilled in the art. The same reference numerals in the figures indicate the same or similar structures, and thus their detailed descriptions will be omitted. In addition, the drawings are only schematic illustrations of the present disclosure, and are not necessarily drawn to scale.

Although relative terms such as “upper” and “lower” are used in this specification to describe the relative relationship between one component and another component shown in the figures, these terms are used in this specification only for convenience, for example, according to the directions of the examples described in the drawings. It can be understood that if the device shown in the figure is turned over, the “upper” component will become the “lower” component. When a structure is “on” other structure, it may indicate that the structure is integrally formed on the other structure, or the structure is “directly” disposed on the other structure, or the structure is “indirectly” disposed on the other structure through another structure.

The terms “one”, “a”, “the” and “said” are used to indicate the presence of one or more elements/components/etc. The terms “include” and “have” are used to indicate open inclusion and indicate that there may be additional elements/components/etc. in addition to the listed elements/components/etc. The terms “first”, “second” and “third” are only used as markers and are not restrictions on the number of objects.

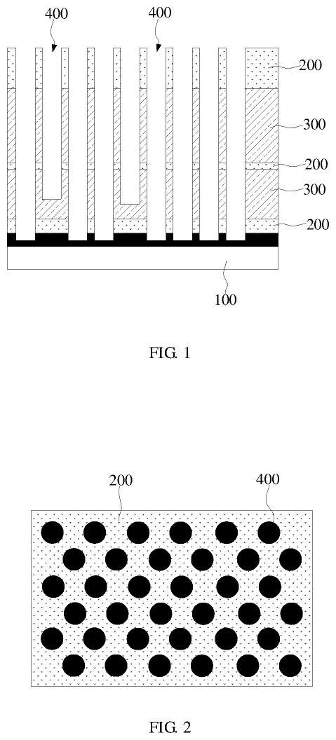

In related technologies, as shown in FIGS. 1 and 2, when a capacitor is manufactured, a support layer 200 and a sacrificial layer 300 that are alternately stacked need to be formed on a substrate 100, the support layer 200 and the sacrificial layer 300 are etched to form a hole-like structure 400 for accommodating the capacitor, and the sacrificial layer 300 is removed after the capacitor is formed. However, due to the limitation of the manufacturing process, the etching depth of a film in different etching regions is different, resulting in insufficient etching of some capacitor holes. After the sacrificial layer 300 is removed, some capacitors will fail due to suspension. Therefore, before the capacitor is formed in the hole-like structure 400, the hole-like structure 400 is usually scanned by a scanning electron microscope, the hole-like structure 400 is irradiated by a detection beam, then a detector of the scanning electron microscope collects detection light scattered or reflected from the hole-like structure 400, finally a bright field image characterizing the etching status of the hole-like structure 400 is obtained, and whether the hole-like structure 400 is etched to the substrate 100 is determined according to the shade of color of the region where each hole-like structure 400 is located in the bright field image. However, when the hole-like structure 400 is of a high depth-width ratio structure, the color difference of the bright field image is not great, it is difficult to identify a defect location, and the defect detection accuracy is low.

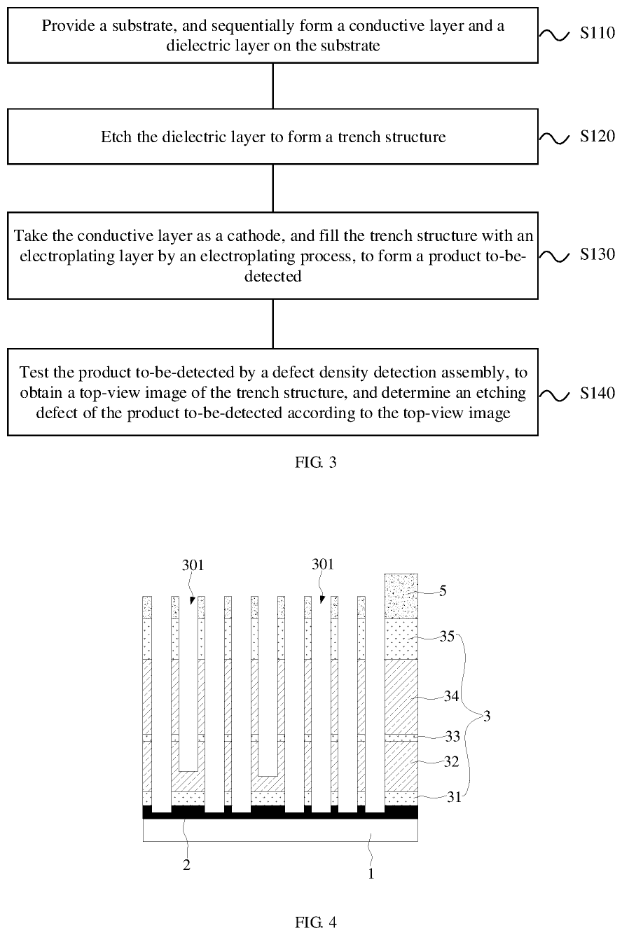

An embodiment of the present disclosure provides an etching defect detection method. As shown in FIG. 3, the detection method may include:

Step S110, providing a substrate on which a conductive layer and a dielectric layer are sequentially formed;

Step S120, etching the dielectric layer to form a trench structure;

Step S130, taking the conductive layer as a cathode, and filling the trench structure with an electroplating layer by an electroplating process, to form a product to-be-detected; and

Step S140, testing the product to-be-detected by a defect density detection assembly, to obtain a top-view image of the trench structure, and determining an etching defect of the product to-be-detected according to the top-view image.

According to the etching defect detection method of the present disclosure, a trench structure with a high depth-width ratio can be formed by etching a dielectric layer, and when an electroplating layer is formed, only the trench structure that exposes a conductive layer after the etching can be formed with the electroplating layer by an electroplating process, taking the conductive layer as a cathode of the electroplating process; with regard to the trench structure that is not etched to the conductive layer, because the conductive layer is not exposed and there is no cathode during the electroplating, the electroplating layer will not be formed, the trench structure that is not filled with the electroplating layer in the top-view image of the product to-be-detected appears with a deep color because of high depth-width ratio, while the trench structure that is filled with the electroplating layer appears in a light color, and then the trench structure that is not etched to the conductive layer can be accurately identified, which improves the accuracy of defect identification, can also avoid the deposition of a capacitor in the trench structure that is not etched to the conductive layer, and prevents the capacitor from failing due to suspension.

Hereinafter, each step of the etching defect detection method according to the embodiment of the present disclosure will be described below in detail:

In step S110, a substrate is provided, and a conductive layer and a dielectric layer are sequentially formed on the substrate.

As shown in FIG. 4, the substrate 1 may have a flat structure, which may be rectangular, circular, elliptical, polygonal or irregular and may be made of silicon or other semiconductor materials. The shape and material of the substrate 1 is not specifically limited here.

The conductive layer 2 and the dielectric layer 3 may be formed on the substrate 1. The conductive layer 2 may be formed on the surface of the substrate 1, and the dielectric layer 3 may be formed on the side of the conductive layer 2 away from the substrate 1. For example, the conductive layer 2 and the dielectric layer 3 may be sequentially formed on the substrate 1 by vacuum evaporation, magnetron sputtering, atomic layer deposition, chemical vapor deposition, or physical vapor deposition.

For example, the conductive layer 2 may be formed on the substrate 1 by vacuum evaporation, and the conductive layer 2 may be a thin film formed on the surface of the substrate 1. In an embodiment, the orthographic projection of the conductive layer 2 on the substrate 1 may coincide with the boundary of the substrate 1. In another embodiment, the conductive layer 2 may include a plurality of electric conductors, and the electric conductors may be distributed in an array on the surface of the substrate 1. In the subsequent process, the electric conductor may be used as a conductive contact plug of a capacitor and may be used to store charges in the capacitor. The material of the conductive layer 2 may be metal, for example, it may be tungsten, of course, it may also be other conductive materials, which is not specifically limited here.

The dielectric layer 3 may be formed on the side of the conductive layer 2 away from the substrate 1 by atomic layer deposition. The dielectric layer 3 may include a single film layer or a plurality of film layers, which is not specifically limited here. In an embodiment, the dielectric layer 3 may include a plurality of film layers. For example, it may include a plurality of support layers and a plurality of sacrificial layers, the support layers and the sacrificial layers are alternately stacked. For example, it may include a first support layer 31, a first sacrificial layer 32, a second support layer 33, a second sacrificial layer 34 and a third support layer 35 that are sequentially and alternately stacked, wherein the first support layer 31 may be formed on the surface of the conductive layer 2.

The first support layer 31, the first sacrificial layer 32, the second support layer 33, the second sacrificial layer 34 and the third support layer 35 may be sequentially formed on the surface of the conductive layer 2 by vacuum evaporation or magnetron sputtering. Of course, the first support layer 31, the first sacrificial layer 32, the second support layer 33, the second sacrificial layer 34 and the third support layer 35 that are alternately stacked may also be formed in other ways, which is not specifically limited here.

In step S120, the dielectric layer is etched to form a trench structure.

As shown in FIG. 4, the dielectric layer 3 may be etched to form a trench structure 301. The trench structure 301 may extend in a direction perpendicular to the substrate 1, and its cross-sectional shape may be circular, rectangular, or irregular. The shape of the trench structure 301 is not specifically limited here. The trench structure 301 may be used for forming of a columnar capacitor, which may be laterally supported by each support layer in the dielectric layer 3, to increase the stability of the columnar capacitor in the lateral direction and prevent the columnar capacitor from being deformed laterally.

During the etching, trench structures 301 with different etching depths appear in different regions of the dielectric layer 3, that is, the trench structure 301 formed by etching in some regions penetrates the dielectric layer 3 to expose the conductive layer 2, while the trench structure 301 formed by etching in other regions does not penetrate the dielectric layer 3, and its end close to the substrate 1 is located in the sacrificial layer or support layer in the dielectric layer 3. In the embodiment of the detection method of the present disclosure, the structure after step S120 is completed is as shown in FIG. 4.

In an embodiment, there may be a plurality of trench structures 301, the plurality of trench structures 301 may be distributed in an array, the number of trench structures 301 may be equal to the number of electric conductors distributed in an array, and each trench structure 301 and each electric conductor may be arranged in one-to-one correspondence in the direction perpendicular to the substrate 1.

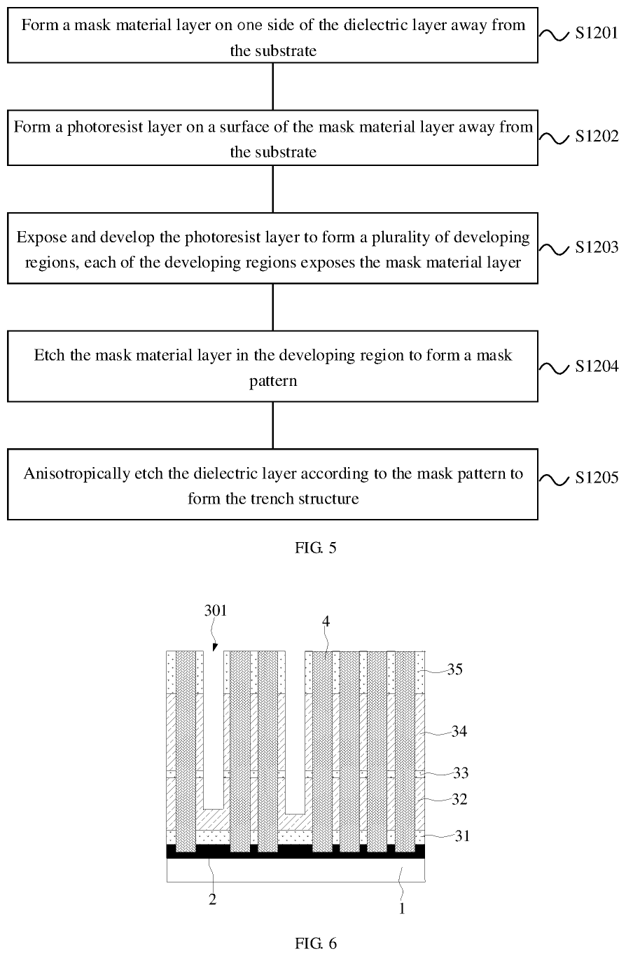

For example, the dielectric layer 3 may be etched by an anisotropic etching process to form the trench structure 301. The dielectric layer 3 may be etched by a single etching process to form the trench structure 301. When the dielectric layer 3 includes a plurality of film layers alternately stacked, the dielectric layer 3 may also be etched in stages, that is, the dielectric layer 3 may be etched multiple times, and only one layer may be etched at a time. In an embodiment of the present disclosure, as shown in FIG. 5, etching the dielectric layer 3 by an anisotropic etching process to form the trench structure 301 may include steps S1201 to S1205.

Step S1201, a mask material layer is formed on the side of the dielectric layer away from the substrate.

The mask material layer 5 may be formed on the side of the dielectric layer 3 away from the substrate 1 by chemical vapor deposition, vacuum evaporation, atomic layer deposition or other ways. The mask material layer 5 may be of a multi-layer or single-layer structure. Its material may be at least one of polymer, SiO₂, SiN, poly and SiCN. Of course, it may also be other materials, which will not be listed here.

In an embodiment, the mask material layer 5 may be multi-layer, including a polymer layer, an oxide layer and a hard mask layer, wherein the polymer layer may be formed on the surface of the dielectric layer 3 away from the substrate 1, and the oxide layer may be located between the hard mask layer and the polymer layer. The polymer layer may be formed on the surface of the dielectric layer 3 away from the substrate 1 by chemical vapor deposition, the oxide layer may be formed on the surface of the polymer layer away from the dielectric layer 3 by vacuum evaporation, and the hard mask layer may be formed on the surface of the oxide layer away from the polymer layer by atomic layer deposition.

Step S1202, a photoresist layer is formed on the surface of the mask material layer away from the substrate.

The photoresist layer may be formed on the surface of the mask material layer 5 away from the substrate 1 by spin coating or other ways. The material of the photoresist layer may be a positive photoresist or a negative photoresist, which is not specifically limited here.

Step S1203, the photoresist layer is exposed and developed to form a plurality of developing regions, each developing region exposes the mask material layer.

The photoresist layer may be exposed by a mask, and the pattern of the mask may match the pattern required by the dielectric layer 3. Subsequently, the exposed photoresist layer may be developed to form a plurality of developing regions, each developing region may expose the mask material layer 5, the pattern of the developing region may be the same as the pattern required by the dielectric layer 3, and the width of the developing region may be the same as the required size of the trench structure 301.

Step S1204, the mask material layer is etched in the developing region to form a mask pattern.

The mask material layer 5 may be etched in the developing region by plasma etching, the dielectric layer 3 may be exposed in the etching region, and then the required mask pattern may be formed on the mask material layer 5. It should be noted that, when the mask material layer 5 is of a single-layer structure, the mask pattern may be formed by a single etching process; and when the mask material layer 5 is of a multi-layer structure, the film layers may be etched separately, that is, one layer may be etched by a single etching process, and the mask layer may be etched thoroughly by multiple times of etching to form the mask pattern.

It should be noted that, after the above etching process is completed, the photoresist layer may be removed by cleaning with a cleaning solution or by ashing, so that the mask material layer 5 is no longer covered by the photoresist layer, and the formed mask layer is exposed to obtain a hard mask structure.

Step S1205, the dielectric layer is anisotropically etched according to the mask pattern to form the trench structure.

The dielectric layer 3 may be anisotropically etched according to the mask pattern. For example, the dielectric layer 3 may be etched in the developing region of the mask pattern by dry etching, and a plurality of trench structures 301 are formed in the dielectric layer 3 by taking the substrate 1 as an etching stop layer. In this process, due to the limitation of the manufacturing process, the etching depths in different regions of the dielectric layer 3 are different, so that a plurality of through holes are formed in some regions of the dielectric layer 3, while one or more hole segments are formed in other regions of the dielectric layer 3, and the end of each hole segment close to the substrate 1 may be located in any sacrificial layer. For example, the end close to the substrate 1 is located in the first sacrificial layer 32.

It should be noted that each through hole may be arranged in one-to-one correspondence with each electric conductor, and the open end of each through hole close to the substrate 1 may be in contact with the surface of the corresponding electric conductor, which facilitates the storage of charges in a capacitor by the electric conductor after the capacitor is formed in the through hole. FIG. 4 shows the structure after step S1205 in the embodiment of the detection method of the present disclosure is completed.

In step S130, the conductive layer is taken as a cathode, and the trench structure is filled with an electroplating layer by an electroplating process, to form a product to-be-detected.

As shown in FIG. 6, taking the conductive layer 2 exposed in the trench structure 301 as the cathode in the electroplating process, the trench structure 301 that exposes the conductive layer 2 is filled with the electroplating layer 4 by the electroplating process, to form the product to-be-detected. It should be noted that, when the electroplating layer 4 is formed, only the trench structure 301 that exposes the conductive layer 2 after the etching can be formed with the electroplating layer 4 by the electroplating process, taking the conductive layer 2 as the cathode of the electroplating process; with regard to the trench structure 301 that is not etched to the conductive layer 2, because the conductive layer 2 is not exposed and there is no cathode during the electroplating, the electroplating layer 4 will not be formed, the trench structure 301 that is not filled with the electroplating layer 4 in the top-view image of the product to-be-detected appears with a deep color because of high depth-width ratio, while the trench structure 301 that is filled with the electroplating layer 4 appears in a light color, and then the trench structure 301 (with an identifiable etching defect) that is not etched to the conductive layer 2 can be identified, which avoids the deposition of a capacitor in the trench structure that is not etched to the conductive layer, and prevents the capacitor from failing due to suspension.

In an embodiment of the present disclosure, as shown in FIG. 7, step S130 may include steps S1301 and S1302.

Step S1301, the conductive layer is taken as a cathode, and the trench structure is filled with an electroplating layer by an electroplating process.

The conductive layer 2 exposed in the trench structure 301 may be taken as a cathode for electroplating, so that positive ions of the pre-plated metal in the plating solution are deposited on the surface of the conductive layer 2 to form the electroplating layer 4. During this process, the trench structure 301 can be filled with the electroplating layer 4 to avoid dark cavities in the top-view image of the trench structure 301, so that the trench structure 301 that is not plated with the electroplating layer 4 is obviously different from the trench structure 301 that is filled with the metal in color in the top-view image, which facilitates the identification of an etching defect.

Step S1302, the part of the electroplating layer higher than the top surface of the trench structure is removed by a chemical mechanical polishing process, so that the surface of the electroplating layer away from the conductive layer is flush with the surface of the dielectric layer away from the conductive layer.

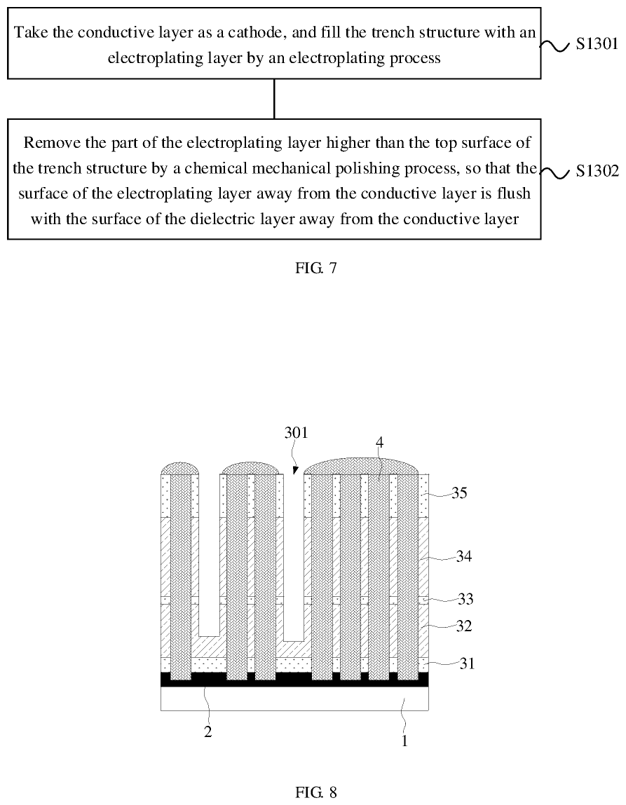

As shown in FIG. 8, during the electroplating, the electroplating layer 4 may be allowed to overflow the top surface of the trench structure 301, so as to ensure that the trench structure 301 is full of the electroplating layer 4. Meanwhile, the part of the electroplating layer 4 higher than the top surface of the trench structure 301 may be removed by the chemical mechanical polishing process, so that the surface of the electroplating layer 4 away from the conductive layer 2 is flush with the surface of the dielectric layer 3 away from the conductive layer 2, which prevents the overflowing electroplating layer 4 from covering the surrounding trench structures 301 that are not etched to the conductive layer 2, and improves the accuracy of defect detection. FIG. 6 shows the structure after step S1302 in the embodiment of the detection method of the present disclosure is completed.

In an embodiment, the part of the electroplating layer 4 higher than the top surface of the trench structure 301 may be removed with a polishing solution. The polishing solution may be water or an acidic solution, which is not particularly limited here, as long as it can remove the excess electroplating layer and does not damage other film layer structures. For example, an acidic solution may be sprayed to the electroplating layer 4 higher than the top surface of the trench structure 301, and the electroplating layer 4 may react with the acidic solution to be removed. The acidic solution may be at least one of hydrochloric acid, nitric acid or acetic acid, of course, it may also be other acidic solutions, which will not be listed here.

In step S140, the product to-be-detected is tested by a defect density detection assembly, to obtain a top-view image of the trench structure, and an etching defect of the product to-be-detected is determined according to the top-view image.

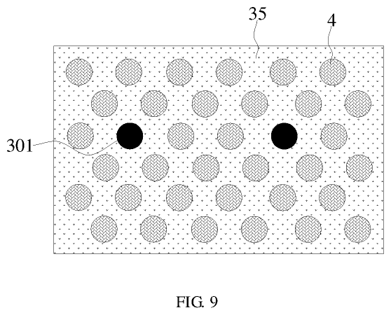

The surface of the dielectric layer 3 away from the substrate 1 in the product to-be-detected may be scanned by the defect density detection assembly, to obtain the top-view image of the trench structure. As shown in FIG. 9, in the top-view image, the regions where the trench structures 301 with high depth-width ratios are located may appear with a deep color, other regions may appear in a light color, and the etching defect may be determined according to the shade of color of each trench structure 301 in the top-view image, that is, the trench structure 301 with the deep color among the trench structures 301 may be identified as an etching defect.

For example, the defect density detection assembly may include at least one of a scanning electron microscope (SEM), an atomic force microscope (AFM), a transmission electron microscope (TEM), and a bright field scanner (BF Scan), and the top-view image may be at least one of a scanning electron microscope pattern, an atomic force microscope map, a transmission electron microscope map, and a bright field scan image. Of course, the defect density detection assembly may also be other instruments or equipment, which will not be listed here.

A person skilled in the art would readily conceive of other embodiments of the present disclosure after considering the specification and practicing the invention disclosed herein. The present application is intended to cover any variations, uses or adaptive changes of the present disclosure. These variations, uses or adaptive changes follow the general principle of the present disclosure and include common general knowledge or conventional technical means in the technical field that are not disclosed in the present disclosure. The description and the embodiments are only regarded as exemplary, and the true scope and spirit of the present disclosure are pointed out by the appended claims.

1. An etching defect detection method, comprising:
providing a substrate, and sequentially forming a conductive layer and a dielectric layer on the substrate;
etching the dielectric layer to form a trench structure;
taking the conductive layer as a cathode, and filling the trench structure with an electroplating layer by an electroplating process, to form a product to-be-detected; and
testing the product to-be-detected by a defect density detection assembly, to obtain a top-view image of the trench structure, and determining an etching defect of the product to-be-detected according to the top-view image.

2. The detection method according to claim 1, wherein there is a plurality of trench structures, and the plurality of trench structures are distributed in an array.

3. The detection method according to claim 2, wherein the determining an etching defect of the product to-be-detected according to the top-view image comprises:
determining the etching defect according to a shade of color of each of the trench structures in the top-view image, and identifying the trench structure with a relatively deep color among the trench structures as the etching defect.

4. The detection method according to claim 1, wherein the taking the conductive layer as a cathode, and filling the trench structure with an electroplating layer by an electroplating process, to form a product to-be-detected comprises:
taking the conductive layer as a cathode, and filling the trench structure with the electroplating layer by the electroplating process; and
removing part of the electroplating layer higher than a top surface of the trench structure by a chemical mechanical polishing process, so that a surface of the electroplating layer away from the conductive layer is flush with a surface of the dielectric layer away from the conductive layer.

5. The detection method according to claim 4, wherein removing part of the electroplating layer higher than a top surface of the trench structure by a chemical mechanical polishing process comprises:
removing the part of the electroplating layer higher than the top surface of the trench structure by a polishing solution, wherein the polishing solution is water.

6. The detection method according to claim 5, wherein the conductive layer comprises a plurality of electric conductors, the electric conductors are distributed in an array on a surface of the substrate, and the electric conductors and the trench structures are arranged in one-to-one correspondence in a direction perpendicular to the substrate.

7. The detection method according to claim 1, wherein the defect density detection assembly comprises at least one of a scanning electron microscope, an atomic force microscope, a transmission electron microscope, and a bright field scanner.

8. The detection method according to claim 1, wherein the dielectric layer comprises a support layer and a sacrificial layer, the support layer and the sacrificial layer are sequentially and alternately stacked, the trench structure is used for forming of a columnar capacitor, and the support layer is configured to support the columnar capacitor laterally.

9. The detection method according to claim 1, wherein the etching the dielectric layer to form a trench structure comprises:
etching the dielectric layer by an anisotropic etching process to form the trench structure.

10. The detection method according to claim 9, wherein the etching the dielectric layer by an anisotropic etching process to form the trench structure comprises:
forming a mask material layer on one side of the dielectric layer away from the substrate;
forming a photoresist layer on a surface of the mask material layer away from the substrate;
exposing and developing the photoresist layer to form a plurality of developing regions, each of the developing regions exposing the mask material layer;
etching the mask material layer in the developing region to form a mask pattern; and
anisotropically etching the dielectric layer according to the mask pattern to form the trench structure.
